(19) United States
(12) Patent Application Publication
(10) Pub. No.: US 2008/0203499 A1
(43) Pub. Date: Aug. 28, 2008

(54) Semiconductor device having gate insulator including high-dielectric-constant materials and manufacture method of the same

(75) Inventor: Kunihiko Iwamoto, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto-Fu (JP)

(21) Appl. No.: 12/068,114

(22) Filed: Feb. 1, 2008

(30) Foreign Application Priority Data
Feb. 19, 2007 (JP) 2007-038644

(51) Int. Cl. H01L 29/423; H01L 21/28

(52) U.S. Cl. 257/411; 438/591; 257/E29.132; 257/E21.177

(57) ABSTRACT

A semiconductor device includes a semiconductor substrate, an insulating layer and a conductive layer disposed on the second insulator, the insulating layer including a first insulator containing silicon and oxygen, an intermediate region containing a metal element, silicon, oxygen and nitrogen, and a second insulator containing the metal element and oxygen, wherein a concentration of the metal element in the intermediate region is higher in a region in contact with the second insulator than in a region in contact with the first insulator.

### CROSS REFERENCE TO RELATED APPLICATIONS AND INCORPORATION BY REFERENCE

This application is based upon and claims the benefit of priority from prior Japanese Patent Application P2007-038644 filed on Feb. 19, 2007; the entire contents of which are incorporated by reference herein.

### BACKGROUND OF THE INVENTION

1. Field of the Invention

The present invention relates to the structure of a semiconductor device and a method for manufacturing the same. In particular, the present invention relates to a semiconductor device having a gate insulator including high-dielectric-constant materials and a method for manufacturing the same.

2. Description of the Related Art

As a metal oxide semiconductor (MOS) transistor for use in a semiconductor integrated circuit, a MOS transistor including a gate insulator containing high-dielectric-constant materials has been known. If the gate insulator containing the high-dielectric-constant materials is used, then a physical thickness of the gate insulator can be thickened while suppressing an equivalent oxide thickness (EOT) in conversion to a silicon oxide film.

However, when the gate insulator containing the high-dielectric-constant materials is directly formed on a silicon substrate, a current drive ability of the MOS transistor is decreased since an interface state density in an interface between the gate insulator and the silicon substrate is increased.

In order to solve such a problem, there has been proposed a method of implementing heat treatment for the gate insulator and a gate electrode (conductive layer) formed on the gate insulator. Here, the gate insulator is composed of a silicon oxide layer formed on the silicon substrate, and of a metal oxide silicate layer that is formed on the silicon oxide layer and contains silicon and the high-dielectric-constant materials. In accordance with this method, the high-dielectric-constant materials contained in the metal oxide silicate layer are diffused into the silicon oxide layer by the heat treatment. Accordingly, a concentration of the high-dielectric-constant materials in the gate insulator becomes low on the silicon substrate side, and becomes high on the gate electrode side. As a result, interface characteristics between the gate insulator and the silicon substrate are maintained.

However, in the above-described method, the metal oxide silicate layer containing silicon is used, and accordingly, there has been a problem that an original dielectric constant of the gate insulator is low.

### SUMMARY OF THE INVENTION

An aspect of the present invention inheres in a semiconductor device. The semiconductor includes a semiconductor substrate; an insulating layer including a first insulator disposed on the semiconductor substrate and containing silicon and oxygen, an intermediate region disposed on the first insulator and containing a metal element, silicon, oxygen and nitrogen, and a second insulator disposed on the intermediate region and containing the metal element and oxygen, wherein a concentration of the metal element in the intermediate region is higher in a region in contact with the second insulator than in a region in contact with the first insulator; and a conductive layer disposed on the second insulator.

Another aspect of the present invention inheres in a method for manufacturing a semiconductor device. The method includes forming a silicon oxide layer containing silicon and oxygen on a semiconductor substrate; forming a first metal oxide layer containing a metal element and oxygen on the silicon oxide layer; and heating the silicon oxide layer and the first metal oxide layer in a nitride atmosphere; wherein a process for forming the first metal oxide layer and a process for heating the silicon oxide layer and the first metal oxide layer are repeated alternately plural times, so that an intermediate region is formed, in which a concentration of the metal element is gradually increased from the semiconductor substrate side along a thickness direction of the semiconductor substrate.

### BRIEF DESCRIPTION OF THE DRAWINGS

FIG. 1 is a cross-sectional view showing the configuration of the semiconductor device according to an embodiment of the present invention;

FIG. 2A is a cross-sectional view showing the configuration of the insulating layer according to the embodiment of the present invention;

FIG. 2B is a graph showing the configuration of the insulating layer according to the embodiment of the present invention;

FIG. 3 is a flowchart explaining a manufacture method of the semiconductor device according to the embodiment of the present invention;

FIGS. 4A to 4C are cross-sectional views for explaining the manufacture method of the semiconductor device according to the embodiment of the present invention;

FIG. 5 is a schematic diagram showing an ALD apparatus used for the manufacture method of the semiconductor device according to the embodiment of the present invention;

FIG. 6 is a cross-sectional TEM photograph of the semiconductor device according to the embodiment of the present invention;

FIG. 7 is a graph showing a composition of the insulating layer according to the embodiment of the present invention;

FIG. 8 is a graph showing a composition of the insulating layer according to the embodiment of the present invention;

FIG. 9 is a graph showing a composition of the insulating layer according to the embodiment of the present invention; and

FIG. 10 is a graph showing a leakage current density of the insulating layer according to the embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

Generally and as it is conventional in the representation of semiconductor devices, it will be appreciated that the various drawings are not drawn to scale from one figure to another nor inside a given figure.

In the following descriptions, numerous specific details are set forth such as specific signal values, etc., to provide a thorough understanding of the present invention. However, it will be obvious to those skilled in the art that the present invention may be practiced without such specific details. In other instances, well-known circuits have been shown in block diagram form in order not to obscure the present invention in unnecessary detail.

### <Configuration of Semiconductor Substrate>

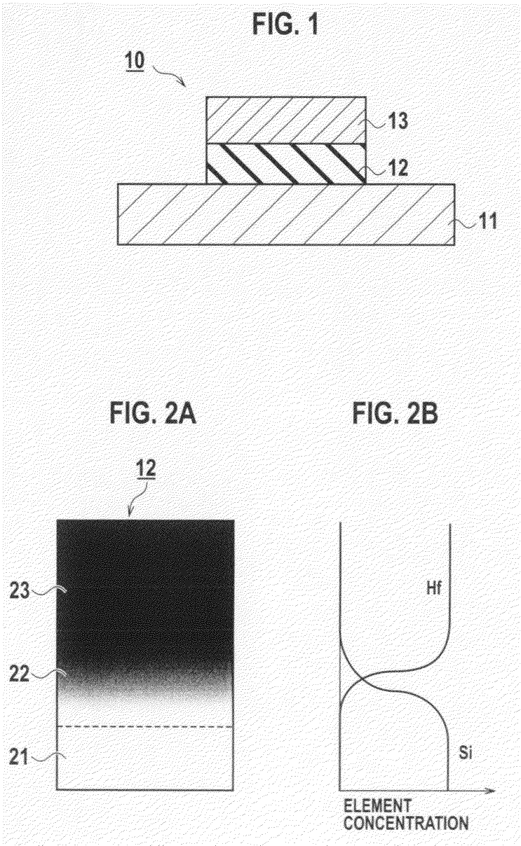

A description will be made below of a configuration of a MOS transistor 10 according to an embodiment of the present invention. FIG. 1 is a cross-sectional view showing the configuration of the MOS transistor 10 according to the embodiment of the present invention.

As shown in FIG. 1, the MOS transistor 10 includes a silicon substrate 11, an insulating layer 12, and a gate electrode 13.

The silicon substrate 11 is a semiconductor substrate with a thin plate shape, in which impurities are diffused into single crystal silicon.

The insulating layer 12 is formed on the silicon substrate 11. As shown in FIG. 2A and FIG. 2B, the insulating layer 12 includes: a silicon oxide region (first insulator) 21 containing silicon (Si) and oxygen (O); an intermediate region 22 containing hafnium (Hf), silicon (Si), oxygen (O) and nitrogen (N); and a metal oxide region (second insulator) 23 containing hafnium (Hf) and oxygen (O). The intermediate region 22 is made of hafnium silicate (HfSiON) containing hafnium as a constituent element. The hafnium silicate is a high-dielectric-constant material, and has a higher dielectric constant than a dielectric constant of silicon oxide. As such a metal element contained in the high-dielectric-constant material, zirconium (Zr) and the like may be employed as well as hafnium.

As shown in FIG. 2B, a concentration of Hf in the intermediate region 22 is gradually increased from the silicon substrate 11 side toward the gate electrode 13 side. Meanwhile, a concentration of Si in the intermediate region 22 is gradually decreased from the silicon substrate 11 side toward the gate electrode 13 side. Hence, also as the entirety of the insulating layer 12, the concentration of Hf is gradually increased from the silicon substrate 11 side toward the gate electrode 13 side, and the concentration of Si is gradually decreased in the same direction. A description will be made later in detail of a method for forming such a concentration gradient.

The gate electrode 13 is formed on the insulating layer 12. As a material of the gate electrode 13, there may be employed: high-melting-point metal materials (SiGe, Ti, Ta, W, Mo, and the like) and nitrides thereof; or silicide materials such as NiSi: as well as polycrystal silicon formed by a chemical vapor deposition (CVD) method.

The semiconductor device, according to the embodiment of the present invention, has a gate insulator in which the interface characteristics with the semiconductor substrate are good, the physical thickness is thick, and the dielectric constant is high.

### <Manufacture Method of Semiconductor Device>

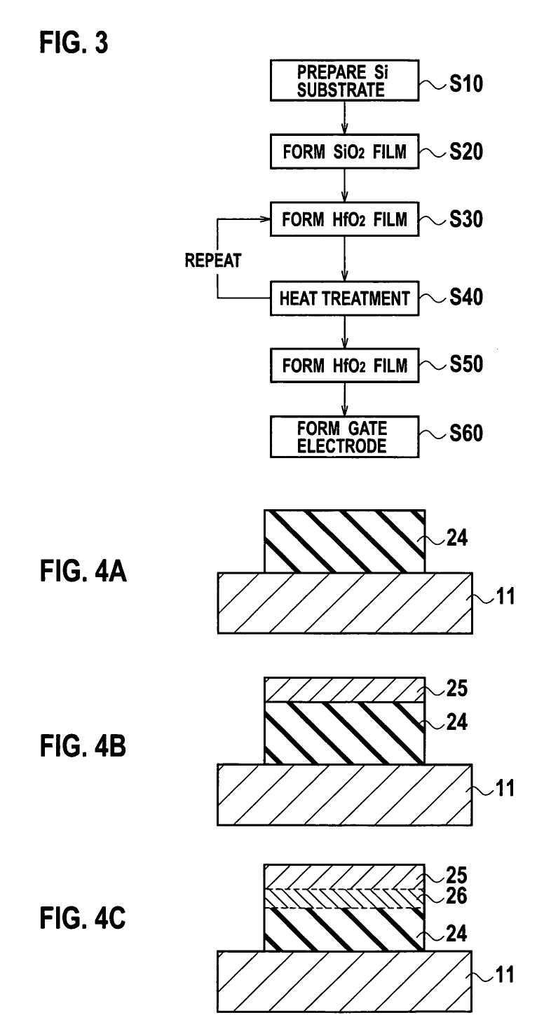

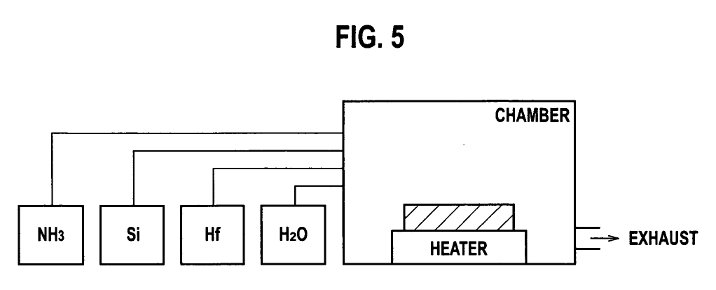

A description will be made of a manufacture method of the MOS transistor 10 according to the embodiment of the present invention by referring to the drawings. FIG. 3 is a flowchart showing the manufacture method of the MOS transistor 10 according to the embodiment of the present invention.

As shown in FIG. 3, in Step S10, the silicon substrate 11 is prepared. A natural oxide on a main surface of the silicon substrate 11 is removed by treatment using a diluted hydrofluoric acid solution, whereby hydrogen termination is performed therefor.

In Step S20, a silicon oxide layer 24 containing Si and oxygen is formed on the main surface of the silicon substrate 11. FIG. 4A is a cross-sectional view showing a state where the silicon oxide layer 24 is formed on the silicon substrate 11. For example, heat treatment is performed for the silicon substrate 11 in an atmosphere to be described below, whereby a silicon oxide (SiO₂) film or a silicon oxide nitride (SiON) film is formed as the silicon oxide layer 24. The silicon oxide layer 24 is formed at a treatment temperature within a range of approximately 700 to 1050° C. in an atmosphere where O₂ and N₂ or H₂ are mixed together by using a rapid thermal annealing (RTA) apparatus. It is preferable that a thickness of the SiO₂ film to be formed be 1.0 nm or more. The silicon oxide layer 24 may be formed by treatment using a chemical solution (a mixed solution of HCl and H₂O₂, and the like), by plasma oxidation treatment, and so on.

In Step S30, a metal oxide layer 25 containing Hf and O is formed on the silicon oxide layer 24 (first process). FIG. 4B is a cross-sectional view showing a state where the metal oxide layer 25 is formed on the silicon oxide layer 24. In this embodiment, an HfO₂ film is formed as the metal oxide layer 25. It is preferable that the HfO₂ film be formed to have a thickness of approximately 0.1 nm. For example, the first process is performed by using an atomic layer deposition (ALD) apparatus. Specifically, H₂O as an oxidant and an organic metal material containing Hf are alternately supplied onto the silicon oxide layer 24, whereby the HfO₂ film is formed. As the organic metal material containing Hf, there may be used: TEMAH (Hf[N(C₂H₅)₂]₄); and TDEAH (Hf[N(CH₃)(C₂H₅)]₄); as well as tetrakis-di-methyl-amino-hafnium (TDMA: Hf[N(CH₃)₂]₄). O₃ may be used as the oxidant. Note that an intermittent CVD method may be used for forming the metal oxide layer 25.

In Step S40, the silicon oxide layer 24 and the metal oxide layer 25 are heated in a nitrogen (N₂) gas atmosphere (second process). The process in Step S40 may be performed by using the RTA apparatus. For example, the heat treatment is performed under conditions where a temperature is approximately 700 to 800° C. and a time is approximately 20 seconds. In such a way, as shown in FIG. 4C, nitrogen is also diffused into a region where HfO₂ is diffused into the SiO₂ film, and a metal silicate layer 26 composed of hafnium silicate (HfSiON) is formed.

Next, the first process in Step S30 and the second process in Step S40 are alternately performed, for example, 20 times. In such a way, the metal silicate layer 26 is formed while gradually converting the silicon oxide layer 24 into the silicate. Specifically, the first process and the second process are alternately repeated, whereby the metal silicate layer 26 is gradually formed, and the intermediate region 22 shown in FIG. 2A is formed. The description has been made above of the case where the first process and the second process are repeated 20 times. However, if SiO₂ remains in an interface between the silicon substrate 11 and the insulating layer 12, then the first process and the second process may be repeated more than 20 times. The number of times that the first process and the second process are repeated may be set at less than 20 times as long as a high dielectric constant of the insulating layer 12 is achieved.

In Step S50, the HfO₂ film is formed on the intermediate region 22 by using the ALD apparatus, whereby the insulating layer 12 is formed.

In Step S60, the gate electrode 13 is formed on the insulating layer 12. For example, polycrystal silicon is formed as the gate electrode 13 by the CVD method.

In a vacuum state, the RTA apparatus and the ALD apparatus are connected to each other while interposing a load lock chamber therebetween. A wafer is moved through these apparatuses by using a carrier apparatus, whereby these steps from Step S20 to Step S50 can be performed in a coordination manner.

From the above, the insulating layer 12 is formed (refer to FIG. 2), which includes the intermediate region 22 in which the concentration of Hf is gradually increased from the silicon substrate 11 side toward the gate electrode 13 side. Moreover, as described above, the concentration of silicon in the intermediate region 22 is gradually decreased from the silicon substrate 11 side toward the gate electrode 13 side.

In accordance with the manufacture method of the semiconductor device, which is described above, a semiconductor device is manufactured, which includes a gate insulator in which the interface characteristics with the semiconductor substrate are good, the physical thickness is thick, and the dielectric constant is high.

### <Function and Effect>

In accordance with the semiconductor device according to the embodiment of the present invention, in order to form the insulating layer 12, the first process for forming, on the silicon oxide layer 24, the metal oxide layer 25 containing the metal element (hafnium) and oxygen and the second process for heating the silicon oxide layer 24 and the metal oxide layer 25 in the nitride atmosphere are repeated alternately plural times after the silicon oxide layer 24 is formed on the silicon substrate 11.

The insulating layer 12 formed as described above includes the intermediate region 22 in which the concentration of Hf is gradually increased from the silicon substrate 11 side toward the gate electrode 13 side. Moreover, on the silicon substrate 11, the silicon oxide region 21 remains. Hence, the good interface characteristics between the silicon substrate 11 and the insulating layer 12 are achieved.

The first process and the second process are repeated alternately plural times, whereby the intermediate region 22 is formed. Accordingly, the diffusion of Hf into the silicon oxide layer 24 is controlled accurately. As a result, the number of times that the first process and the second process are repeated is controlled, thus making it possible to accurately control the thickness of the silicon oxide region 21 remaining on the silicon substrate 11.

The second process is performed so that the intermediate region 22 composed of hafnium silicate is formed. Accordingly, the impurities owing to the organic metal material in the first process do not remain in the insulating layer 12. Therefore, a density of defects in an inside of the insulating layer 12 is reduced, and electric characteristics thereof are enhanced.

The heat treatment in the second process is performed in the nitride atmosphere, and accordingly, nitrogen can be selectively introduced into the intermediate region 22. As a result, chemical bonding of the hafnium silicate is stabilized.

### EXAMPLE

The semiconductor device according to the embodiment of the present invention is manufactured in the following manner.

First, heat treatment is performed in an oxidation atmosphere, whereby a SiO₂ film with a thickness of 1.0 nm is formed on a silicon substrate. Forming conditions are set such that O₂ gas is used, a treatment temperature is 900° C., a treatment time is 20 sec, and a treatment pressure is 20 Torr.

An HfO₂ film with a thickness of 0.1 nm is deposited on the SiO₂ film by the ALD method (first process). Deposition conditions are set such that TDMAH is used as the material of Hf, H₂O is used as the oxidant, a heater temperature is 250° C., and a deposition pressure is approximately 13 Pa.

Heat treatment is performed in a nitride atmosphere (second process). Treatment conditions are set such that a treatment temperature is 750° C., a treatment time is 20 sec, and a treatment pressure is 20 Torr.

Then, the first process and the second process are repeated alternately 20 times.

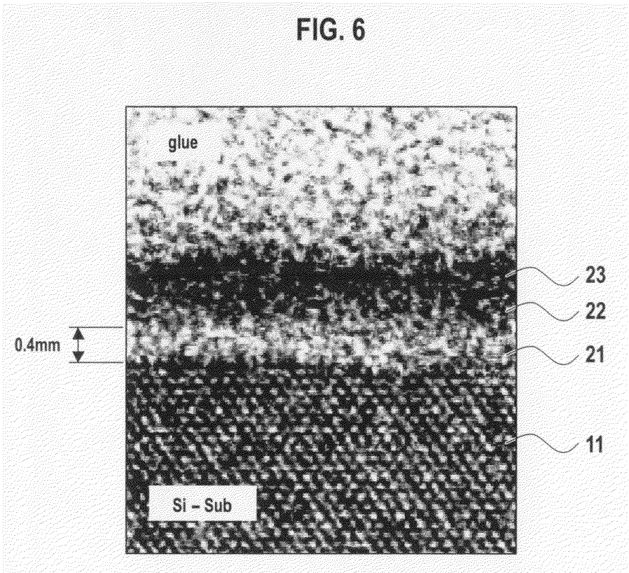

With regard to the semiconductor device of the embodiment, which is manufactured as described above, a transmission electron microscope (TEM) picture of a cross section thereof is shown in FIG. 6. As shown in FIG. 6, as a result of repeating the first process and the second process alternately 20 times, it is confirmed that the thickness of the SiO₂ film that is originally formed to have a thickness of 1.0 nm is thinned to 0.4 nm.

### <Composition of Insulating Layer 12>

Next, the insulating layer 12 according to the embodiment is successively subjected to etching treatment from the metal oxide layer side, whereby a composition of the insulating layer 12 is evaluated.

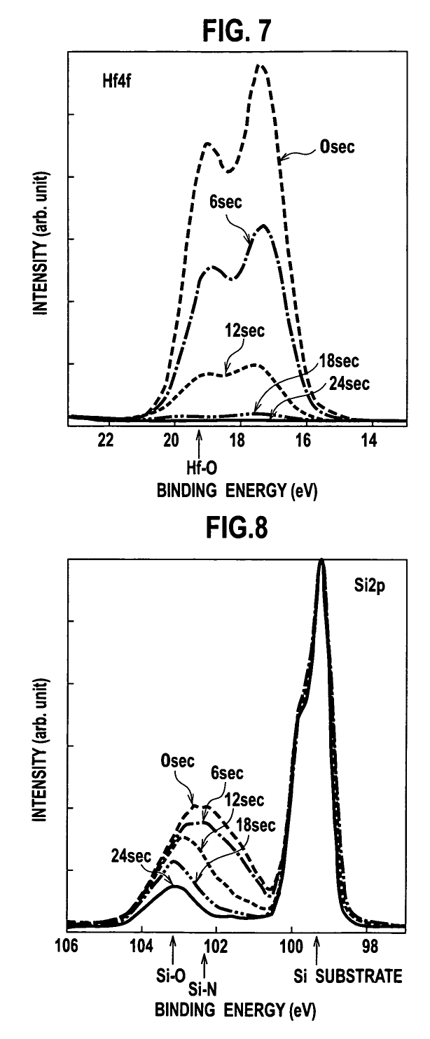

Evaluation results are shown in FIG. 7 to FIG. 9. As shown in FIG. 7, Hf—O is not detected any longer after elapse of 24 seconds from the start of the etching treatment. Moreover, as shown in FIG. 8, Si—N is not detected any longer after the elapse of 24 seconds from the start of the etching treatment, and in place of Si—N, Si—O is detected. Hence, it is confirmed that, in the insulating layer 12, the concentration of Hf is gradually decreased from the gate electrode 13 side toward the semiconductor substrate 11 side, and the silicon oxide layer remained on the semiconductor substrate 11.

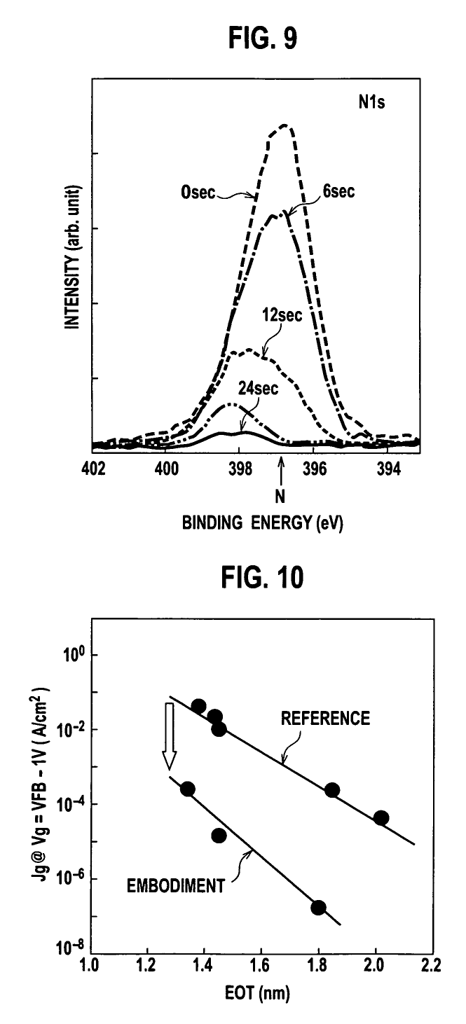

Moreover, as shown in FIG. 9, at the time when Hf is not detected any longer (that is, after the elapse of 24 seconds from the start of the etching treatment), N is not detected any longer, either. Hence, it is confirmed that N existed only in the intermediate region composed of hafnium silicate.

### <Gate Leakage Current Density>

A relationship between a gate leakage current density and EOT of the insulating layer of the embodiment is shown in FIG. 10. It is confirmed that a magnitude of a gate leakage current in the embodiment reduces to about 1/100 in comparison with the gate leakage current in a reference sample with a general double-layer structure of the HfO₂ film and the SiO₂ film, which does not have the intermediate region.

The reason why such a result is obtained is that the insulating layer 12 according to the embodiment is formed to be thick in terms of the physical thickness while suppressing the increase of the EOT, and that the defect density in the inside thereof is low.

Various modifications will become possible for those skilled in the art after receiving the teachings of the present disclosure without departing from the scope thereof.

What is claimed is:

1. A semiconductor device comprising:
a semiconductor substrate;
an insulating layer including:
a first insulator disposed on the semiconductor substrate and containing silicon and oxygen;
an intermediate region disposed on the first insulator and containing a metal element, silicon, oxygen and nitrogen; and
a second insulator disposed on the intermediate region and containing the metal element and oxygen,
wherein a concentration of the metal element in the intermediate region is higher in a region in contact with the second insulator than in a region in contact with the first insulator; and
a conductive layer disposed on the second insulator.

2. The semiconductor device of claim 1, wherein
after forming a silicon oxide layer containing silicon and oxygen on the semiconductor substrate, a first process for forming a metal oxide layer containing the metal element and oxygen on the silicon oxide layer and a second process for heating the silicon oxide layer and the metal oxide layer in a nitride atmosphere are repeated alternately plural times, whereby the intermediate region is formed.

3. The semiconductor device of claim 1, wherein the concentration of the metal element in the intermediate region is gradually increased from the region in contact with the first insulator toward the region in contact with the second insulator.

4. The semiconductor device of claim 1, wherein a concentration of silicon in the intermediate region is gradually decreased from the region in contact with the first insulator toward the region in contact with the second insulator.

5. The semiconductor device of claim 1, wherein a dielectric constant of the intermediate region is higher than a dielectric constant of the first insulator.

6. The semiconductor device of claim 1, wherein the intermediate region includes a high-dielectric-constant material.

7. The semiconductor device of claim 6, wherein the metal element is one of hafnium and zirconium.

8. The semiconductor device of claim 1, wherein the first insulator further contains nitrogen.

9. The semiconductor device of claim 1, wherein a region of the first insulator, the region being in contact with the semiconductor substrate, is a silicon oxide layer including silicon and oxygen.

10. A method for manufacturing a semiconductor device, comprising:
forming a silicon oxide layer containing silicon and oxygen on a semiconductor substrate;
forming a first metal oxide layer containing a metal element and oxygen on the silicon oxide layer; and
heating the silicon oxide layer and the first metal oxide layer in a nitride atmosphere;
wherein a process for forming the first metal oxide layer and a process for heating the silicon oxide layer and the first metal oxide layer are repeated alternately plural times, so that an intermediate region is formed, in which a concentration of the metal element is gradually increased from the semiconductor substrate side along a thickness direction of the semiconductor substrate.

11. The method of claim 10, further comprising:
diffusing nitrogen into a region of the silicon oxide layer, into which the metal element is diffused, by the process for heating the silicon oxide layer and the first metal oxide layer, in order to form a metal silicate layer.

12. The method of claim 10, further comprising:
forming a second metal oxide film on the intermediate region.

13. The method of claim 12, further comprising:
forming a conductive layer on the second metal oxide film.

14. The method of claim 10, wherein a dielectric constant of the intermediate region is higher than a dielectric constant of the silicon oxide layer.

15. The method of claim 10, wherein the intermediate region includes a high-dielectric-constant material.

16. The method of claim 15, wherein the metal element is one of hafnium and zirconium.
